(19) United States
(12) Patent Application Publication
(10) Pub. No.: US 2026/0269591 A1
(43) Pub. Date: Sep. 10, 2026

(54) BUSBAR SYSTEM

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: KUO-CHUN HSU, New Taipei (TW); HSIU-YUAN HSU, New Taipei (TW); MIN-SI WU, New Taipei (TW)

(21) Appl. No.: 19/555,081

(22) Filed: Mar. 3, 2026

(30) Foreign Application Priority Data
Mar. 4, 2025 (CN) 202510246974.6

(51) Int. Cl. H02G 5/10

(52) U.S. Cl. CPC H02G 5/10

(57) ABSTRACT

A busbar system includes a busbar assembly and a housing surrounding the busbar assembly. The busbar assembly has a power busbar and a ground return busbar electrically isolated from the power busbar. The housing forms flow channels for liquid to pass between the housing and each of the power busbar and the ground return busbar. This configuration effectively reduces fluid flow resistance, thereby improving heat dissipation efficiency.

### BACKGROUND OF THE INVENTION

### Field of the Invention

The present invention relates to a busbar system, and more particularly to a busbar system with reliable heat dissipation.

### Description of Related Arts

U.S. Pat. No. 12,178,019 discloses a busbar assembly comprising a power busbar, a ground return busbar, a first thermal conduit disposed on the power busbar for dissipating heat from the power busbar, and a second thermal conduit disposed on the ground return busbar for dissipating heat from the ground return busbar. However, the approach of using two separate thermal conduits to dissipate heat results in limited contacting areas of the thermal conduits with the power busbar and the ground return busbar. Consequently, the thermal conduits are unable to reliably dissipate heat from the busbar assembly.

### SUMMARY OF THE INVENTION

A busbar system comprising: a busbar assembly and a housing surrounding the busbar assembly. The busbar assembly having a power busbar and a ground return busbar electrically isolated from the power busbar. The housing forms flow channels for liquid to pass between the housing and each of the power busbar and the ground return busbar.

### BRIEF DESCRIPTION OF DRAWINGS

FIG. 1 shows a perspective view of the busbar system of the present invention;

FIG. 2 shows an exploded perspective view of the busbar system of the present invention;

FIG. 3 shows an exploded perspective view of the busbar system from another angle;

FIG. 4 shows an exploded perspective view of the busbar assembly of the present invention;

FIG. 5 shows a further exploded perspective view of the busbar assembly of the present invention;

FIG. 6 shows the further exploded perspective view of the busbar assembly from another angle; and

FIG. 7 shows a sectional view of the busbar system of the present invention.

### DETAILED DESCRIPTION OF THE DRAWINGS

Reference will now be made in detail to the preferred embodiments of the present invention.

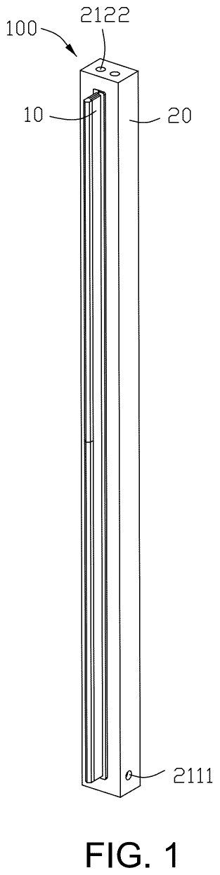

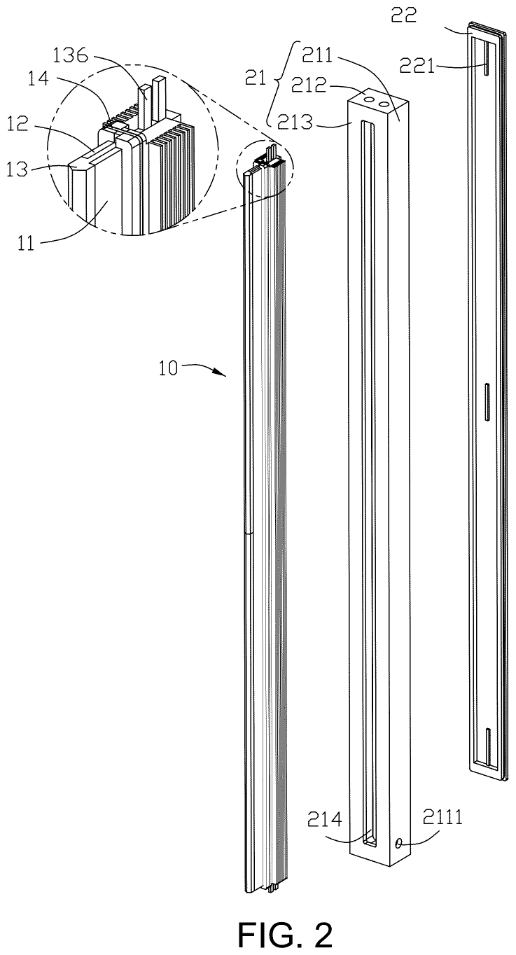

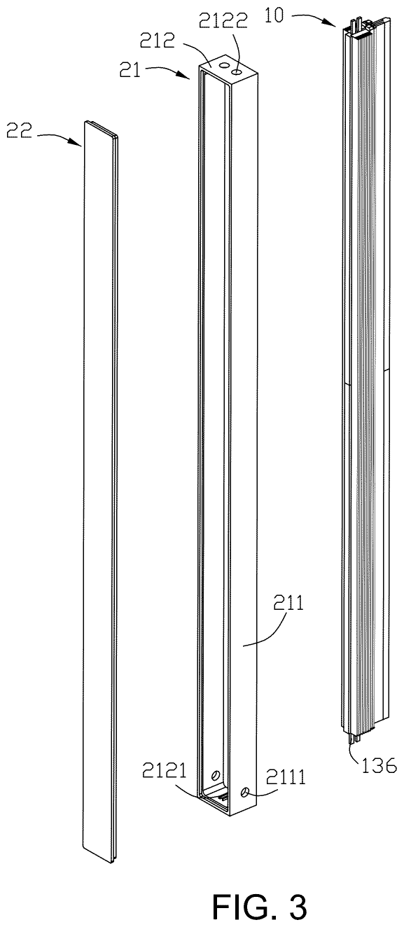

Referring to FIGS. 1-3, the present invention discloses a busbar system 100 for connecting electrical components (not shown) to supply power to the electrical components (not shown). The busbar system 100 includes a busbar assembly 10 and a housing 20 surrounding the busbar assembly 10. The busbar assembly 10 is installed within the housing 20. The housing 20 includes a base portion 21 and a rear wall 22 mating with the base portion 21. The base portion 21, serving as a rearwardly opening sink, comprises a pair of side walls 211 extending in a vertical direction, a pair of end walls 212 connecting the side walls 211, and a front wall 213 connecting the side walls 211 and the end walls 212. The front wall 213 is provided with a slot 214 which allows the busbar assembly 10 to pass through. The rear wall 22 is installed from rear to front onto the base portion 21. In other embodiments, the assembly method of the base portion 21 and the rear wall 22 may be any configuration that can enclose the busbar assembly 10 and allow liquid to pass through. The housing 20 surrounds the busbar assembly 10 so that the busbar assembly 10 can be immersed in liquid, increasing the heat dissipation area of the busbar assembly.

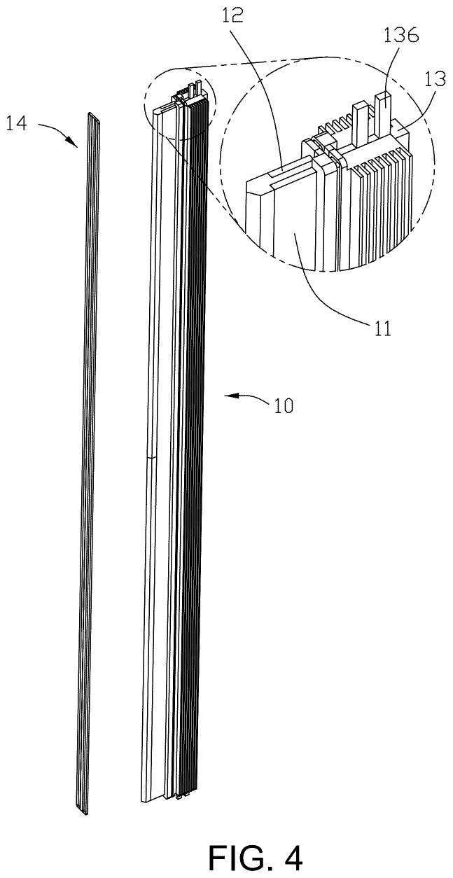

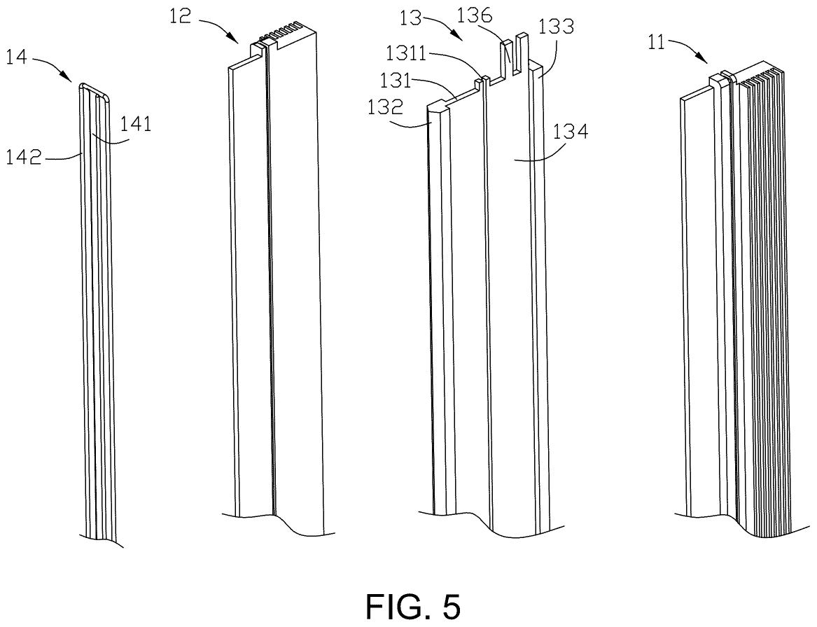

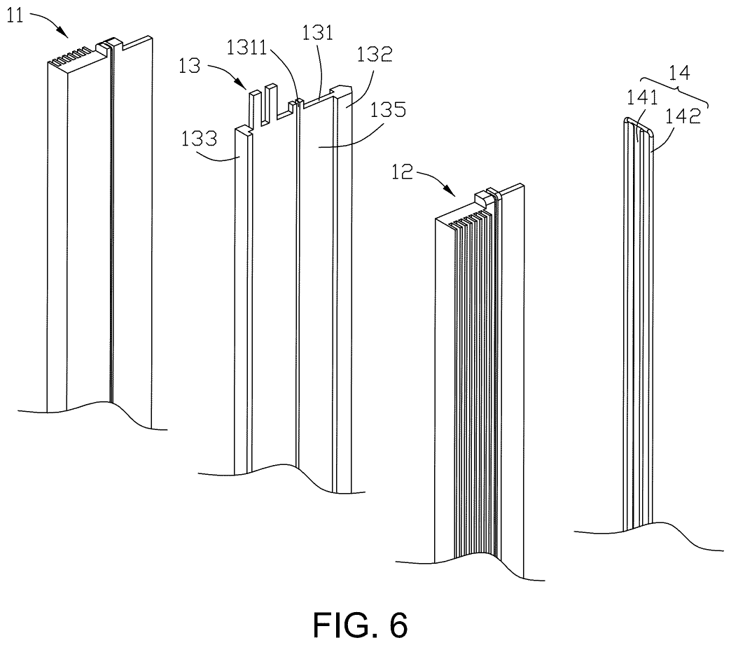

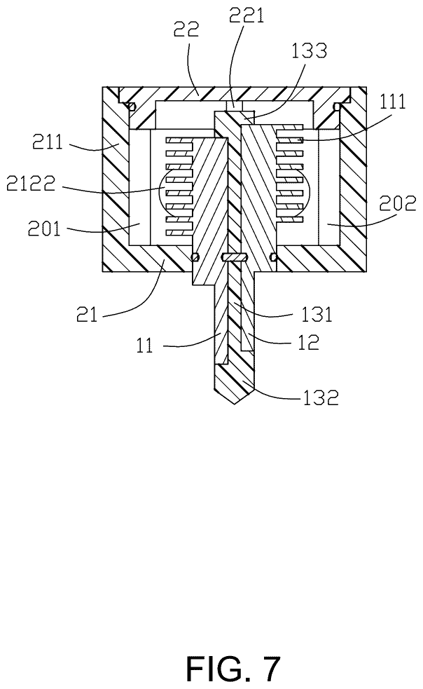

Referring to FIGS. 4-7, the busbar assembly 10 includes a power busbar 12, a ground return busbar 11 electrically isolated from the power busbar 12, an isolation plate 13, and a sealing member 14. The power busbar 12 and the ground return busbar 11 are long plate-shaped members extending in the vertical direction. The isolation plate 13 is disposed between the power busbar 12 and the ground return busbar 11 and extends the entire height in the vertical direction of the power busbar 12 and the ground return busbar 11, electrically isolating the power busbar 12 from the ground return busbar 11. The power busbar 12 and the ground return busbar 11, together with the isolation plate 13, form a busbar element for supplying power to the electrical components (not shown). The isolation plate 13 includes a substrate 131, a front protrusion 132 at the front end of the substrate 131 with a greater thickness than that of the substrate 131, and a rear protrusion 133 at the rear end of the substrate 131 with a greater thickness than that of the substrate 131. One side of the substrate 131, together with the front protrusion 132 and the rear protrusion 133, forms a first groove 134 for embedding the power busbar 12, while the other side of the substrate 131, together with the front protrusion 132 and the rear protrusion 133, forms a second groove 135 for embedding the power busbar 12.

In the present invention, the isolation plate 13 is sandwiched between the power busbar 12 and the ground return busbar 11. However, in other embodiments, the power busbar 12 and the ground return busbar 11 may also be electrically isolated by a gap formed by air.

Both the power busbar 12 and the ground return busbar 11 have a thick rear portion and a thin front portion. The rear portions of the power busbar 12 and the ground return busbar 11 are accommodated within the receiving cavity, and the outer side of the front portion of the power busbar 12 forms a mating interface for mating with the electrical components (not shown) to provide a power supply path. The outer side of the front portion of the ground return busbar 11 forms a mating interface for mating with the electrical components to provide a power return path. The busbar assembly 10 is sealed to the housing 20 by a sealing member 14 disposed at the rear portion.

The busbar assembly 10 is installed from rear to front into the base portion 21, with the front portions of the power busbar 12 and the ground return busbar 11 passing through the slot 214. The sealing member 14 is disposed at the front end of the busbar assembly 10 for sealing engagement with the slot 214. Furthermore, the rear wall 22 is sealingly installed from rear to front at the rear end of the base portion 21. The base portion 21 and the rear wall 22 form a box body for accommodating the busbar assembly 10. A first flow channel 201 is formed between the housing 20 and the power busbar 12, and a second flow channel 202 is formed between the housing 20 and the ground return busbar 11. The end wall 212 is provided with a guide groove 2121, and the upper and lower ends of the isolation plate 13 are respectively provided with protrusions 136 that mate with the guide groove 2121. The busbar assembly 10 is installed into the base portion 21 by the engagement of the protrusions 136 and the guide groove 2121. The rear wall 22 is provided with a restricting portion 221 at a position corresponding to the isolation plate 13. When the rear wall 22 is installed to the base portion 21, the restricting portion 221 abuts against the isolation plate 13 to ensure stable retention of the busbar assembly 10 in a front-rear direction perpendicular to the vertical direction. The restricting portion 221 comprises several ribs, with gaps between the ribs to allow mutual flow between the first flow channel 201 and the second flow channel 202. Liquid flows into the first flow channel 201 and the second flow channel 202 for cooling the power busbar 12 and the ground return busbar 11.

Meanwhile, a pair of inlets 2111 is provided on the side wall 211, and a pair of outlets 2122 is provided on the end wall 212. The pair of outlets 2122 is located on the left and right sides of the guide groove 2121 to correspond to the first flow channel 201 and the second flow channel 202, respectively. The power busbar 12 and the ground return busbar 11 further include several heat dissipation fins 111 protruding toward the side wall 211, thereby increasing the heat dissipation area of the busbars in the first flow channel 201 and the second flow channel 202. The heat dissipation fins 111 are long plate-shaped members extending in the vertical direction and are arranged at intervals in the front-rear direction. The surface area of the power busbar 12 and the ground return busbar 11 exposed in the first flow channel 201 and the second flow channel 202 are subjected to insulation treatment.

Liquid enters the first flow channel 201 and the second flow channel 202 from the pair of inlets 2111, passing through guide slots between the heat dissipation fins 111, and flow out of the first flow channel 201 and the second flow channel 202 from the outlets 2122. Each of the first flow channel 201 and the second flow channel 202 has a corresponding inlet 2111 and outlet 2122, allowing relatively independent flow and effectively reducing flow resistance. At the same time, the first flow channel 201 and the second flow channel 202 can communicate with each other through the gaps, so that when one of the left or right sides of the busbar assembly 10 is blocked, the liquid can flow into the flow channel on the other side through the gaps to complete heat dissipation, preventing unilateral overheating.

The sealing member 14 includes a base 141 disposed between the isolation plate 13 and the power busbar 12 and the ground return busbar 11, and a sealing ring 142 surrounding the front end of the power busbar 12 and the ground return busbar 11. The substrate 131 is provided with a recess 1311 for accommodating the base 141. The recess 1311 divides the substrate 131 into two parts in the front-rear direction.

However, the disclosure is illustrative only, changes may be made in detail, especially in matter of shape, size, and arrangement of parts within the principles of the invention.

1. A busbar system comprising:
a busbar assembly having a power busbar and a ground return busbar electrically isolated from the power busbar; and
a housing surrounding the busbar assembly; wherein
the housing forms flow channels for liquid to pass between the housing and each of the power busbar and the ground return busbar.

2. The busbar system of claim 1, further comprising an isolation plate provided between the power busbar and the ground return busbar to electrically isolate the power busbar from the ground return busbar, and wherein: the isolation plate extends along the entire height of the power busbar and the ground return busbar in a vertical direction; the isolation plate comprises a substrate, a front protrusion at a front end of the substrate having a greater thickness than the substrate, and a rear protrusion at a rear end of the substrate having a greater thickness than the substrate; and one side of the substrate, together with the front and rear protrusions, forms a first groove for embedding the power busbar, and the other side of the substrate, together with the front and rear protrusions, forms a second groove for embedding the ground return busbar.

3. The busbar system of claim 2, wherein:
the busbar assembly further comprises a sealing member disposed at a front end of the power busbar and the ground return busbar;
the sealing member includes a base disposed between the isolation plate and each of the power busbar and the ground return busbar and a sealing ring surrounding the front end of the power busbar and the ground return busbar;
the substrate is provided with a recess for accommodating the base; and
the substrate is divided by the recess into two parts in a front-rear direction.

4. The busbar system of claim 1, wherein the power busbar and the ground return busbar both extend in a vertical direction, and the housing comprises a base portion with a receiving cavity and a rear wall sealingly fitting to the base portion.

5. The busbar system of claim 4, wherein:
the receiving cavity of the base portion opens rearwardly to allow the busbar assembly to be installed from rear to front;
the base portion comprises a pair of side walls extending in the vertical direction, a pair of end walls connecting the side walls, and a front wall connecting the side walls and the end walls; and
the front wall is provided with a slot for the power busbar and the ground return busbar to pass through.

6. The busbar system of claim 5, wherein the power busbar and the ground return busbar further comprise a plurality of heat dissipation fins protruding toward the side walls; the heat dissipation fins extend in the vertical direction and are formed as long plate-shaped members, and are arranged at intervals in a front-rear direction perpendicular to the vertical direction.

7. The busbar system of claim 5, wherein:
each of the power busbar and the ground return busbar has a thick rear portion and a thin front portion;
the rear portions of the power busbar and the ground return busbar are accommodated within the receiving cavity;
an outer surface of the front portion of the power busbar forms a mating interface for providing a power path to electrical components;
an outer surface of the front portion of the ground return busbar forms a mating interface for providing a ground return path to the electrical components;
the busbar assembly comprises a sealing member provided at the rear portions to seal with the housing; and
surfaces of the power busbar and the ground return busbar within the receiving cavity are treated for insulation.

8. The busbar system of claim 5, further comprising an isolation plate provided between the power busbar and the ground return busbar to electrically isolate the power busbar from the ground return busbar, and wherein the end wall is provided with a guide groove, the isolation plate includes a protrusion matching the guide groove, and the busbar assembly is installed into the base portion from rear to front via the protrusion.

9. The busbar system of claim 8, wherein the rear wall is fitted to the base portion from rear to front, and the rear wall includes a restricting portion abutting the busbar assembly to retain the busbar assembly in a front-rear direction.

10. The busbar system of claim 9, wherein the power busbar and the base portion form a first flow channel; the ground return busbar and the base portion form a second flow channel; the rear wall includes plural restricting portions and gaps are provided between the plural restricting portions; the first flow channel and the second flow channel are in fluid communication with each other through the gaps; at least one of the side wall and the end wall is provided with an inlet and an outlet; and each of the first flow channel and the second flow channel has one inlet and one outlet.

11. The busbar system of claim 10, wherein the power busbar and the ground return busbar further comprise several heat dissipation fins protruding toward the side walls; the fins extend in the vertical direction; and the inlet and the outlet are respectively located at upper and lower sides of the fins.

12. A busbar system comprising:
a busbar assembly comprising a power busbar and a ground return busbar electrically isolated from the power busbar; and
a housing surrounding the busbar assembly; wherein
the housing comprises a pair of side walls, a pair of end walls connecting the side walls, a front wall and a rear wall connecting the side walls and the end walls; and
the busbar assembly is partially accommodated in the housing and is spaced from the side walls.

13. The busbar system of claim 12, wherein the front wall is provided with a slot for the power busbar and the ground return busbar to pass through; the side walls, the end walls, and the front wall of the housing form a base portion; and the rear wall is sealingly fitted to the base portion to form a receiving cavity for accommodating the busbar assembly.

14. The busbar system of claim 12, wherein the power busbar is spaced from one side wall to form a first flow channel for liquid to pass through; the ground return busbar is spaced from the other side wall to form a second flow channel for liquid to pass through; and surfaces of the power busbar and the ground return busbar exposed in the first and second flow channels are treated for insulation.

15. The busbar system of claim 12, wherein the power busbar and the ground return busbar further comprise a plurality of heat dissipation fins protruding toward the side walls; the fins extend in a vertical direction as long plate-shaped members and are arranged at intervals in a front-rear direction perpendicular to the vertical direction.

16. The busbar system of claim 15, wherein guide slots for liquid to pass through are formed between every two adjacent fins, and each guide slot penetrates upper and lower sides of the power busbar and the ground return busbar.

17. A busbar system comprising:
a busbar assembly comprising a power busbar and a ground return busbar electrically isolated from the power busbar; and
a housing surrounding the busbar assembly; wherein
the housing includes a receiving cavity for accommodating the busbar assembly;
each of the power busbar and the ground return busbar includes a rear portion accommodated in the receiving cavity and a front portion extending forwardly out of the receiving cavity; and
the receiving cavity is filled with liquid to immerse the rear portions accommodated therein.

18. The busbar system of claim 17, wherein a surface area of the power busbar and the ground return busbar in contact with the liquid is greater than a surface area of the power busbar and the ground return busbar outside the housing.

19. The busbar system of claim 17, wherein the power busbar and the ground return busbar further comprise a plurality of heat dissipation fins protruding toward the side walls; the fins extend in a vertical direction as long plate-shaped members and are arranged at intervals in a front-rear direction perpendicular to the vertical direction; and the fins are immersed in the liquid.

20. The busbar system of claim 17, wherein the housing comprises a pair of side walls extending in the vertical direction; a pair of end walls connecting the side walls, and a front wall and a rear wall connecting the side walls and the end walls; the side walls, the end walls, the front wall, and the rear wall together form the receiving cavity; and the front wall is provided with a slot for the power busbar and the ground return busbar to pass through.
